(19) United States
(12) Patent Application Publication
(10) Pub. No.: US 2011/0128709 A1
(43) Pub. Date: Jun. 2, 2011

(54) Display array substrate and method of manufacturing display substrate

(75) Inventors: Woon Chun Kim, Suwon (KR); Soon Gyu Yim, Seongnam (KR); Jong Young Lee, Suwon (KR)

(73) Assignee: Samsung Electro-Mechanics Co., Ltd., Suwon (KR)

(21) Appl. No.: 12/805,216

(22) Filed: Jul. 19, 2010

(30) Foreign Application Priority Data
Nov. 27, 2009 (KR) 10-2009-0115493

(51) Int. Cl. H05K 7/00; H05K 3/00

(52) U.S. Cl. 361/748; 29/829

(57) ABSTRACT

A display array substrate according to an aspect of the invention may include: a substrate wafer having a plurality of substrates and cutting portions connecting the plurality of substrates to a dummy area, the substrate wafer being diced to provide individual substrates by cutting the cutting portions; and a transparent electrode part coated over one surface of the substrate wafer.

### CROSS-REFERENCE TO RELATED APPLICATIONS

This application claims the priority of Korean Patent Application No. 10-2009-0115493 filed on Nov. 27, 2009, in the Korean Intellectual Property Office, the disclosure of which is incorporated herein by reference.

### BACKGROUND OF THE INVENTION

1. Field of the Invention

The present invention relates to a display array substrate and a method of manufacturing a display substrate, and more particularly, to an array substrate including substrates applied to display devices and a method of manufacturing a plurality of substrates at the same time by dicing this array substrate.

2. Description of the Related Art

Touch type personal portable devices detect whether a user touches display devices, and the entire devices produce vibrations upon the user's touch.

Here, a touch type display device may refer to an input device that detects a location of a touch by a user on a display screen and performs the general control of electronic equipment, including the display screen control, on the basis of information about the detected contact location as input information.

Furthermore, this touch type display device includes a vibration element. When the user touches the touch type display device, the vibration element provides feedback to the touch through vibrations. The vibration element may be disposed along the edge of the display device.

This touch type display device may be divided into a resistive overlay touch display device, a capacitive overlay touch display device and the like, according to operating schemes thereof. In particular, a capacitive overlay touch display device detects a location of a touch by a user according to capacitance variations caused by the user's touch being applied to a front face of a display window. The application range of this capacitive touch display device has been gradually increased due to its high durability and suitability for sliding type inputs.

A transparent electrode for detecting capacitance variations is provided on a display substrate of this capacitive type display device. In order to manufacture this display device, a large-sized display array substrate is provided and then diced into unit display substrates.

However, when the large-sized display array substrate is diced to manufacture unit display substrates, cracks occur in the transparent electrode formed on the display substrate due to a force generated when dicing the display array substrate, or delaminations occur around the cutting surfaces. Therefore, there is a need for techniques to solve these problems.

### SUMMARY OF THE INVENTION

An aspect of the present invention provides a display array substrate and a method of manufacturing display substrates that can prevent cracks or delaminations from occurring in a transparent electrode.

According to an aspect of the present invention, there is provided a display array substrate including: a substrate wafer having a plurality of substrates and cutting portions connecting the plurality of substrates to a dummy area, the substrate wafer being diced to provide individual substrates by cutting the cutting portions; and a transparent electrode part coated over one surface of the substrate wafer.

The cutting portions may be arranged in the middle of four edges of each of the plurality of substrates.

The cutting portions may be located at corners of each of the substrates.

The cutting portions may have a smaller thickness than the substrates.

The cutting portions may have the same thickness as the plurality of substrates.

The transparent electrode may include at least one of a ceramic, a conductive polymer or a mixture containing carbon.

According to another aspect of the present invention, there is provided a method of manufacturing a display substrate, the method including: providing a substrate wafer having a plurality of substrates and cutting portions connecting the plurality of substrates to a dummy area so that the substrate wafer is diced to provide individual substrates by cutting the cutting portions; forming a transparent electrode part on one surface of the substrate wafer; and dicing the substrate wafer along the cutting portions in order to manufacture substrates having a predetermined size.

The cutting portions may have the same thickness as the substrates.

The cutting portions may have a smaller thickness than the substrates.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a perspective view illustrating a personal portable terminal to which a display substrate is applied according to an exemplary embodiment of the present invention;

FIG. 2 is a cross-sectional view illustrating the operating principle of the display substrate of FIG. 1;

FIGS. 3 through 5 are cross-sectional views and plan views illustrating a display array substrate according to an exemplary embodiment of the present invention and a method of manufacturing display substrates from the array substrate;

FIGS. 6 through 8 are cross-sectional views and plan views illustrating a display array substrate according to another exemplary embodiment of the present invention and a method of manufacturing display substrates from the array substrate;

FIGS. 9 through 11 are cross-sectional views and plan views illustrating a display array substrate according to another exemplary embodiment of the present invention and a method of manufacturing display substrates from the array substrate; and

FIGS. 12 through 14 are cross-sectional views and plan views illustrating a display array substrate according to another exemplary embodiment of the present invention and a method of manufacturing display substrates from the array substrate.

### DETAILED DESCRIPTION OF THE PREFERRED EMBODIMENT

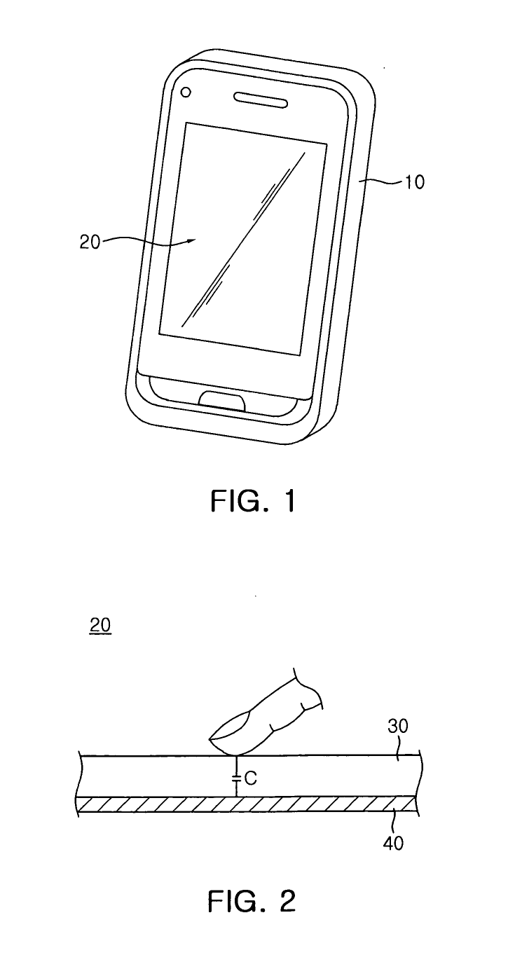

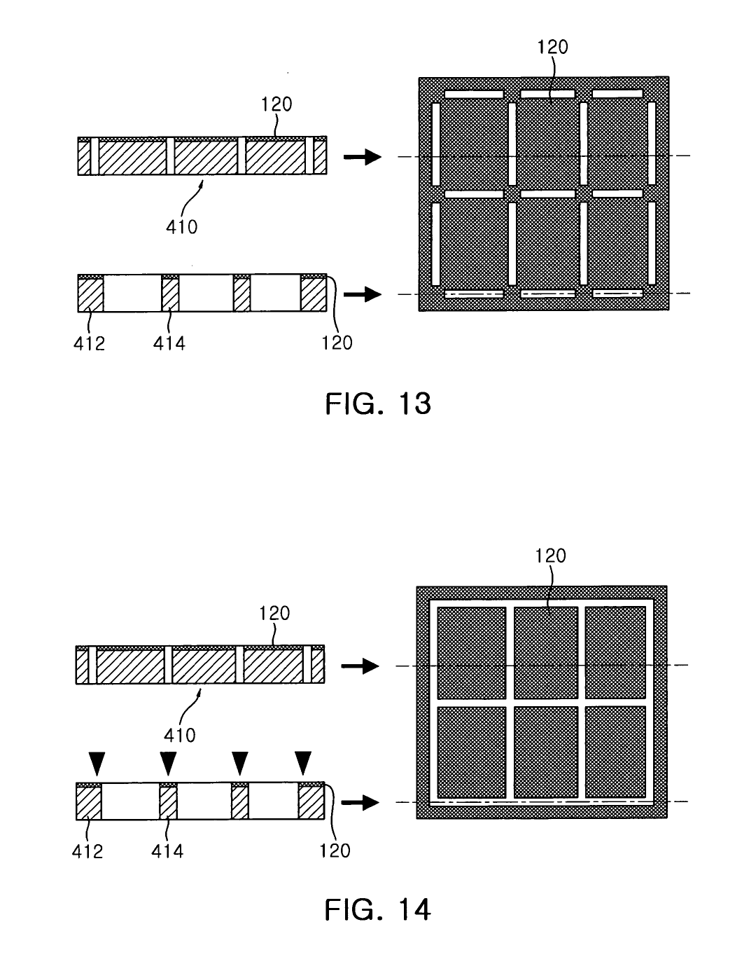

A display array substrate and a method of manufacturing display substrates will be described in detail with reference to FIGS. 1 through 14. Exemplary embodiments of the present invention will now be described in detail with reference to the accompanying drawings.

The invention may, however, be embodied in many different forms and should not be construed as being limited to the embodiments set forth herein. While those skilled in the art could readily devise many other varied embodiments that incorporate the teachings of the present invention through the addition, modification or deletion of elements, such embodiments may fall within the scope of the present invention.

In the drawings, the same reference numerals will be used throughout to designate the same or like components.

FIG. 1 is a perspective view illustrating a personal portable terminal to which a display substrate is applied according to an exemplary embodiment of the invention. FIG. 2 is a cross-sectional view illustrating the operating principle of the display substrate, shown in FIG. 1.

Referring to FIGS. 1 and 2, a display substrate 20 may be mounted on a display device that is formed on a front face of the personal portable device 10. The display substrate 20 may be the above-described touch type display device.

The display substrate 20 may include a substrate part 30, a transparent electrode 40, and a piezoelectric actuator (not shown).

The substrate part 30 is mounted on the front face of the personal portable device 10, and may be formed of a transparent material such as tempered glass or acryl having a uniform thickness or dielectric constant.

The transparent electrode 40 is formed on one face of the substrate part 30. As shown in FIG. 2, the transparent electrode 40 detects capacitance variations of the substrate part 30. Therefore, when a user touches the substrate part 30 at a predetermined position with a part of a user's body, for example, a fingertip, variations occur in capacitance C generated between the transparent electrode 40 at the corresponding position and the body contact surface. A control unit calculates X-directional and Y-directional components on the basis of data concerning the variations of the capacitance.

The piezoelectric actuator (not shown) may be designed 165 such that the piezoelectric actuator is driven according to a contact signal. Also, the piezoelectric actuator may be arranged at the side of the substrate part 30. However, the position of the piezoelectric actuator is not limited thereto, and may be located at various positions according to the 170 designers' intentions.

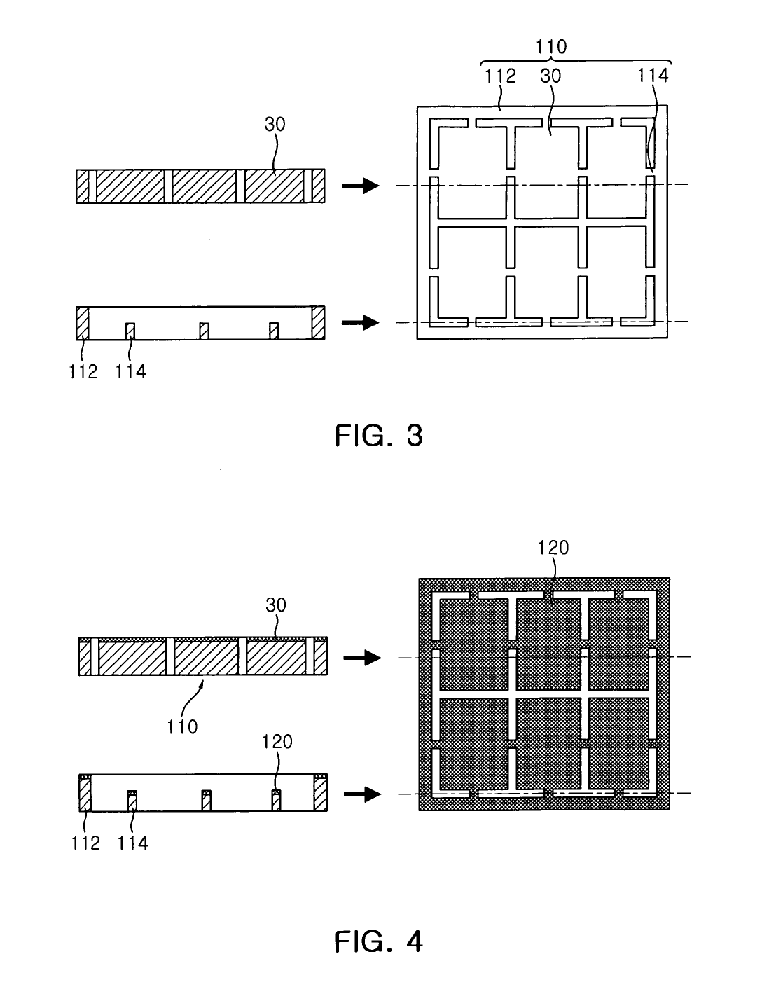

FIGS. 3 through 5 are cross-sectional views and plan views each illustrating a display array substrate according to an exemplary embodiment of the present invention and a method of manufacturing display substrates from the array substrate.

Referring to FIGS. 3 through 5, a display array substrate 100 includes a substrate wafer 110 and a transparent electrode part 120.

The substrate wafer 110 has a plurality of substrate parts 30 formed in a single body and being applicable to personal 180 portable devices. The plurality of substrate parts 30 are connected to a dummy area 112 so that the substrate wafer 110 is diced into substrate size.

The substrate parts 30 are connected to the dummy area 112 through cutting portions 114. Here, the cutting portions 185 114 may be formed in the middle of the four edges of the substrate part 30. However, the positions of the cutting portions 114 are not limited thereto, and the cutting portions 114 may be arranged at various positions according to the designers' intentions.

Here, the cutting portions 114 may have a smaller thickness than the substrate part 30. Each of the cutting portions 114 may be approximately half of the thickness of the substrate part 30. Therefore, it can be easier to cut the cutting portions 114 having a smaller thickness.

The substrate wafer 110 may be formed of a transparent material such as tempered glass or acryl having a uniform thickness or dielectric constant.

The transparent electrode part 120 may be coated over one surface of the substrate wafer 110. Alternatively, the transparent electrode part 120 may be formed on top surfaces of the cutting portions 114 and the surface of the substrate part 30.

The transparent electrode part 120 may be formed of at least one of a ceramic, a conductive polymer or a mixture containing carbon. Here, the conductive polymer may be polythiophene (PEDOT) or polyaniline, the ceramic may be ITO, IZO, AZO, GZO, FTO or ZnO, and the mixture containing carbon may be CNT, graphene or carbon black. The transparent electrode part 120 may have the same structure as the above-described transparent electrode 40.

Therefore, in order to manufacture the substrate parts 30, the substrate wafer 110 is diced along the cutting portions 114. Since the cutting portions 114 have a small thickness, the substrate wafer 110 can be diced by applying a small force to 215 separate the substrate parts 30.

Furthermore, since the cutting portions 114 and the transparent electrode part 120 have heights different from one another, it is possible to prevent the impact, being generated during the dicing operation, from being directly transmitted to the transparent electrode part 120, thereby preventing the delaminations of the transparent electrode part 120 by the above force.

A method of manufacturing display substrates will now be illustrated.

First, as shown in FIG. 3, according to a method of manufacturing display substrates, the substrate wafer 110 having the plurality of substrate parts 30 connected to the dummy area 112 through the cutting portions 114 is provided.

Here, the cutting portions 114 may have a smaller 230 thickness than the substrate parts 30. The cutting portions 114 may be formed in the middle of the four edges of each of the substrate part 30.

As shown in FIG. 4, the transparent electrode part 120 may be formed on one surface of the substrate wafer 110 having the substrate parts 30 connected to the dummy area 112 through the cutting portions 114.

Therefore, the transparent electrode part 120 may be formed on the substrate parts 30 except for grooves around the substrate parts 30 and the surface of the dummy area 112.

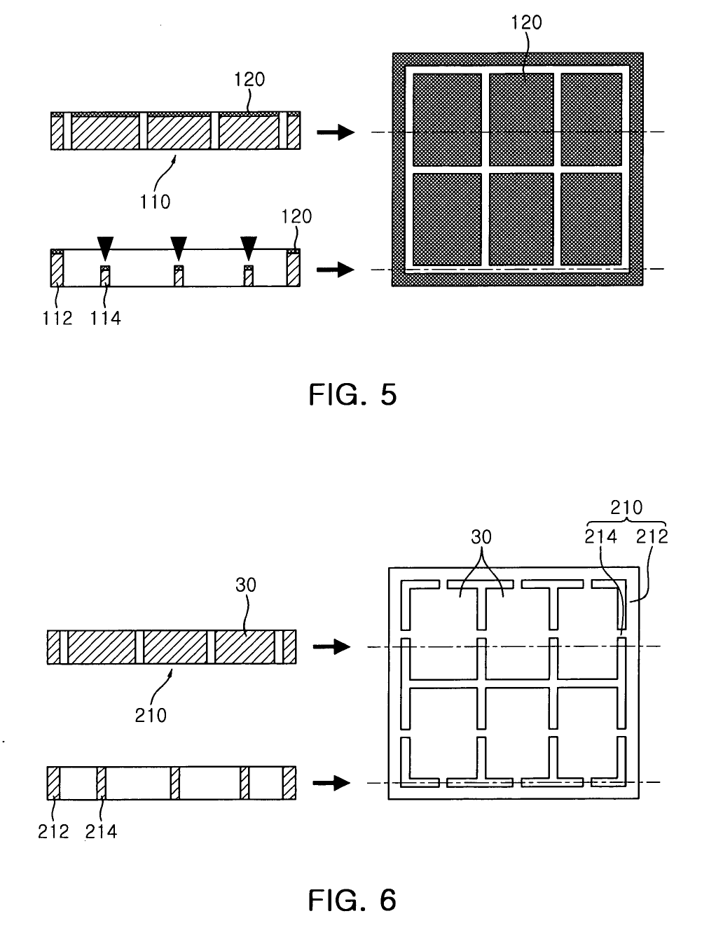

Then, as shown in FIG. 5, in order to manufacture individual substrates having a predetermined size, the substrate wafer 110 is diced by cutting the cutting portions 114 alone (in the direction of the arrow depicted therein).

Instead of cutting each of the substrate parts 30 along the entire outer circumference, the cutting portions 114 are only cut. Therefore, it is possible to separate the substrate parts 30 by applying a smaller force than that in the related art. It is also possible to prevent the occurrence of cracks or delaminations in the transparent electrode part 120 caused when the substrate parts 30 along the entire outer circumference.

Furthermore, according to the display array substrate and the method of manufacturing display substrates, the impact, generated when the substrate wafer 110 is cut along the cutting portions 114, can be prevented from being directly transmitted to the transparent electrode part 120 formed on the surfaces of the substrate parts 30 since the cutting portions 114 on the substrate wafer 110 may have a smaller thickness than the substrate parts 30. Therefore, the durability of the display substrates can be improved.

FIGS. 6 through 8 are cross-sectional views and plan views illustrating a display array substrate according to another exemplary embodiment of the invention and a method of manufacturing display substrates from the array substrate.

Referring to FIGS. 6 through 8, according to a method of manufacturing display substrates, a substrate wafer 210 having a plurality of substrate parts 30 connected to a dummy area 212 through cutting portions 214 is provided.

Here, the cutting portions 214 may have the same thickness as the substrate parts 30. The cutting portions 214 may be formed in the middle of the four edges of each of the substrate parts 30.

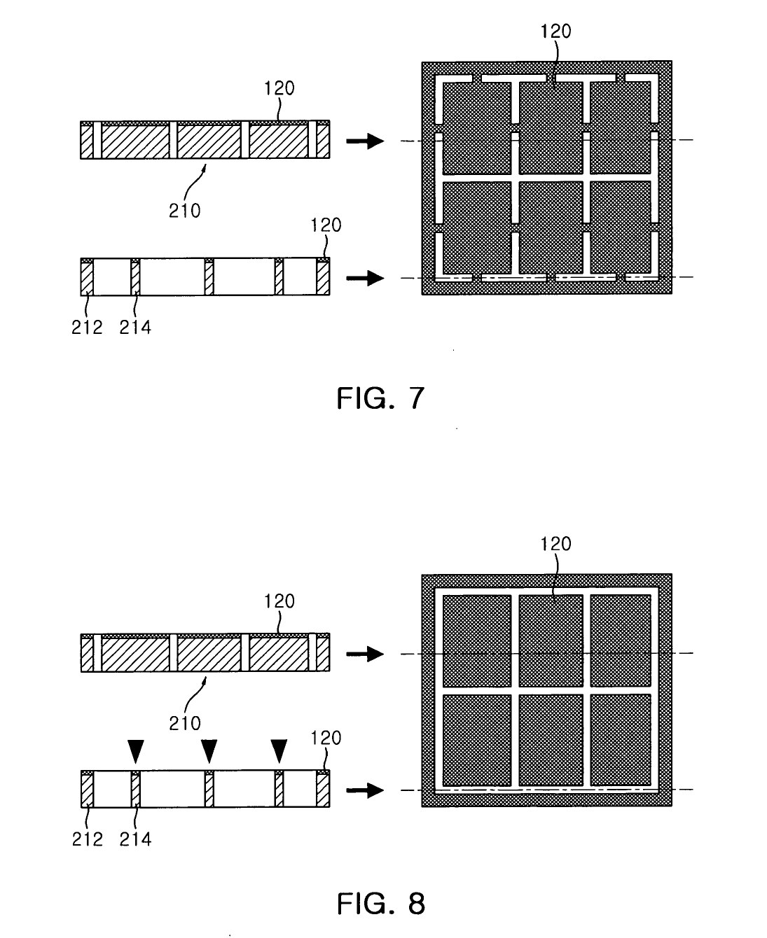

Then, as shown in FIG. 7, the transparent electrode part 120 may be formed on one surface of the substrate wafer 210 having the substrate parts 30 connected to the dummy area 212 through the cutting portions 214.

Then, as shown in FIG. 8, in order to manufacture substrates having a predetermined size, the substrate wafer 210 is diced by cutting the cutting portions 214 alone.

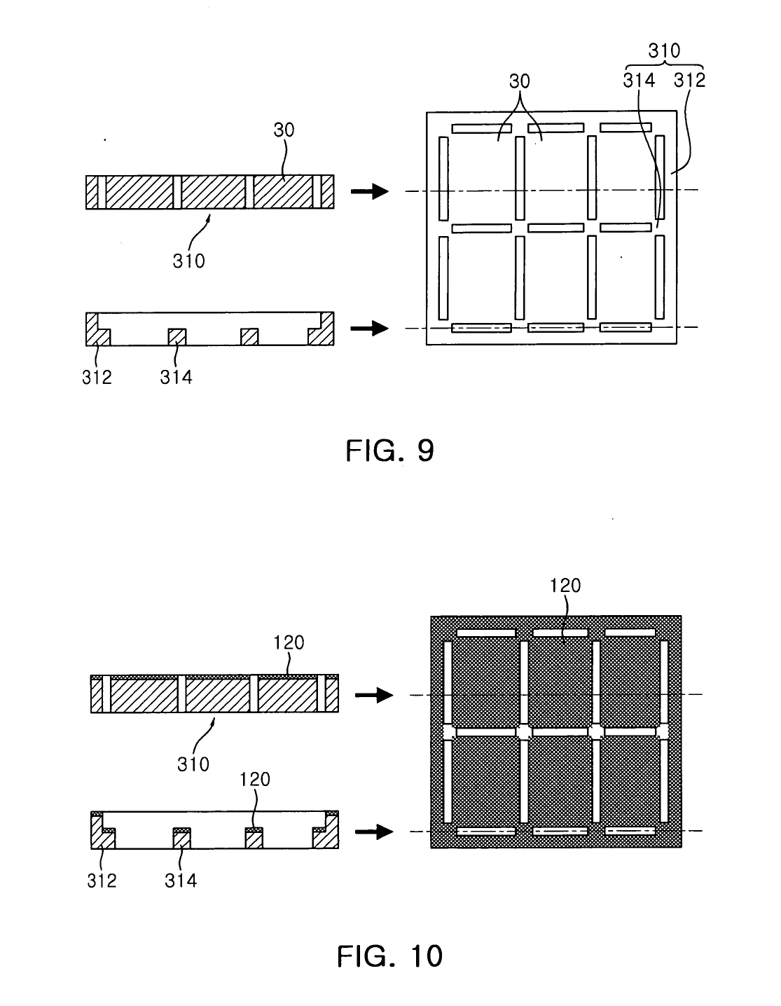

FIGS. 9 through 11 are cross-sectional views and plan views illustrating a display array substrate and a method of manufacturing display substrates from the array substrate.

Referring to FIGS. 9 through 11, according to a method of manufacturing display substrates, a substrate wafer 310 having a plurality of substrate parts 30 connected to a dummy area 312 through cutting portions 314 is provided.

The cutting portions 314 may have a smaller thickness than the substrate parts 30. The cutting portions 214 may be formed at the four corners of each of the substrate parts 30. Therefore, in this case, the number of cutting portions 314 can be reduced.

Then, as shown in FIG. 10, the transparent electrode part 120 may be formed on one surface of the substrate wafer 310 including the substrate parts 30 connected to the dummy area 312 through the cutting portions 314.

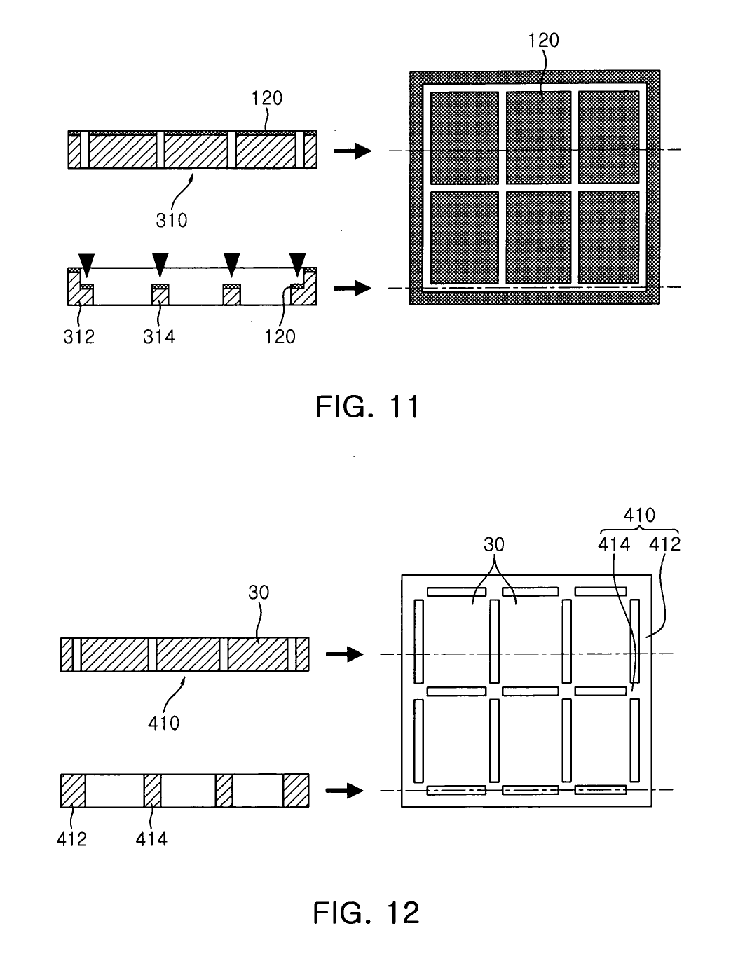

Then, as shown in FIG. 11, in order to manufacture substrates having a predetermined size, the substrate wafer 310 is diced by cutting the cutting portions 314 alone.

FIGS. 12 through 14 are cross-sectional views and plan views illustrating a display array substrate according to another exemplary embodiment of the invention and a method of manufacturing display substrates from the array substrate.

Referring to FIGS. 12 through 14, according to a method of manufacturing display substrates, a substrate wafer 410 having the plurality of substrate parts 30 connected to a dummy area 412 through cutting portions 414 is provided.

Here, the cutting portions 414 may have the same thickness as the substrate parts 30. The cutting portions 414 may be formed at the four corners of each of the substrate parts 30. Therefore, the number of cutting portions 314 can be reduced.

Then, as shown in FIG. 12, the transparent electrode part 120 may be formed on one surface of the substrate wafer 410 including the substrate parts 30 connected to the dummy area 412 through the cutting portions 414.

Then, as shown in FIG. 11, in order to manufacture substrates having a predetermined size, the substrate wafer 410 is diced by cutting the cutting portions 414 alone.

Therefore, substrates are separated from the substrate wafers 210, 310, and 410 by simply cutting the cutting portions 214, 314, and 414 connecting the dummy areas to the substrates, thereby simplifying a manufacturing process. Furthermore, since a great force is not applied during the manufacturing process, thereby reducing incidental impact and minimizing the force to be applied to the transparent electrode part 120.

Therefore, delaminations or cracks in the transparent electrode part 120 can be prevented.

As set forth above, according to exemplary embodiments of the invention, in a display array substrate and a method of manufacturing display substrates, as a substrate wafer having a plurality of substrates and cutting portions connecting the substrates to a dummy area is included, only the cutting portions are cut to thereby easily separate and manufacture the substrates.

Furthermore, according to exemplary embodiments of the invention, since substrates are separated by cutting the cutting portions alone, the wafer substrate can be diced by applying a minimal force, the impact generated during the dicing operation can be prevented from being transmitted to a transparent electrode, and the durability of the display substrates can be improved.

While the present invention has been shown and described in connection with the exemplary embodiments, it will be apparent to those skilled in the art that modifications and variations can be made without departing from the spirit and scope of the invention as defined by the appended claims.

What is claimed is:

1. A display array substrate comprising:
a substrate wafer having a plurality of substrates and cutting portions connecting the plurality of substrates to a dummy area, the substrate wafer being diced to provide individual substrates by cutting the cutting portions; and
a transparent electrode part coated over one surface of the substrate wafer.

2. The display array substrate of claim 1, wherein the cutting portions are arranged in the middle of four edges of each of the plurality of substrates.

3. The display array substrate of claim 1, wherein the cutting portions are located at corners of each of the substrates.

4. The display array substrate of claim 1, wherein the cutting portions have a smaller thickness than the substrates.

5. The display array substrate of claim 1, wherein the cutting portions have the same thickness as the plurality of substrates.

6. The display array substrate of claim 1, wherein the transparent electrode comprises at least one of a ceramic, a conductive polymer or a mixture containing carbon.

7. A method of manufacturing a display substrate, the method comprising:
providing a substrate wafer having a plurality of substrates and cutting portions connecting the plurality of substrates to a dummy area so that the substrate wafer is diced to provide individual substrates by cutting the cutting portions;
forming a transparent electrode part on one surface of the substrate wafer; and
dicing the substrate wafer along the cutting portions in order to manufacture substrates having a predetermined size.

8. The method of claim 7, wherein the cutting portions have the same thickness as the substrates.

9. The method of claim 7, wherein the cutting portions have a smaller thickness than the substrates.
